(19) United States
(12) Patent Application Publication
(10) Pub. No.: US 2026/0255554 A1
(43) Pub. Date: Aug. 27, 2026

(54) INTEGRATED CONTROLLER FOR VEHICLE

(71) Applicant: HANON SYSTEMS, Daejeon (KR)

(72) Inventors: Dong Kyu LEE, Daejeon (KR); Chung Jae BAEK, Daejeon (KR); Sungun SHIM, Daejeon (KR); Su Han KWON, Daejeon (KR); Ho Jun SEO, Daejeon (KR)

(21) Appl. No.: 19/162,797

(22) PCT Filed: Mar. 6, 2024
(86) PCT No.: PCT/KR2024/002857

§ 371 Date: Sep. 5, 2025

(30) Foreign Application Priority Data
Mar. 6, 2023 (KR) 10-2023-0029167

(51) Int. Cl. H05K 7/20; B60H 1/00; B60R 16/023; H05K 5/00

(52) U.S. Cl. CPC H05K 7/20872; B60H 1/00642; B60R 16/023; H05K 5/0069

(57) ABSTRACT

The present invention relates to an integrated controller for a vehicle, and more particularly, to an integrated controller that integrally controls two or more electrical components of a thermal management system for a vehicle. The present invention integrally controls two or more electrical components using a single integrated controller, thereby providing the advantages of achieving cost competitiveness, easy system optimization, and improved system reliability.

### TECHNICAL FIELD

The present invention relates to an integrated controller for a vehicle, and more specifically, to an integrated controller that integrally controls two or more of electrical components of a thermal management system for a vehicle.

### BACKGROUND ART

Examples of eco-friendly vehicles include electric vehicles, hybrid vehicles, fuel cell vehicles, and the like (hereinafter collectively referred to as “vehicles”). These vehicles have various thermal management devices. For example, there are an air conditioner for cooling and heating the interior of a vehicle, a water-cooled battery cooling unit for cooling batteries, a water-cooled electrical component module cooling unit for cooling electrical component modules, etc.

The air conditioner is of a heat pump type and has a refrigerant circulation line, and the refrigerant circulation line includes a compressor, a high-pressure side indoor thermal exchanger, an expansion valve for a heat pump mode, an outdoor thermal exchanger, an expansion valve for an air conditioner mode, and a low-pressure side indoor thermal exchanger. This refrigerant circulation line enables a refrigerant of the compressor to circulate in the order of the high-pressure side thermal exchanger→the outdoor thermal exchanger→the expansion valve for an air conditioner mode→the low-pressure side indoor thermal exchanger. In addition, through this refrigerant circulation, low-temperature cold air is generated in the low-pressure side indoor thermal exchanger, and the generated cold air cools the interior of the vehicle.

In addition, in the heat pump mode, the refrigerant of the compressor may circulate in the order of the high-pressure side indoor thermal exchanger→the expansion valve for a heat pump mode→the outdoor thermal exchanger. In addition, through this refrigerant circulation, high-temperature heat is generated in the high-pressure side indoor thermal exchanger, and the generated heat is supplied into the vehicle for heating.

The water-cooled battery cooling device cools a battery using a refrigerant of an air conditioner and includes a chiller that introduces the refrigerant of the air conditioner to generate cold air, and a battery-side coolant circulation line that transfers the cold air generated from the chiller to the battery. In particular, the battery-side coolant circulation line circulates coolant between the chiller and the battery. Accordingly, the cold air generated from the chiller is transferred to the battery to cool the battery.

A water-cooled electrical component module cooling device has a coolant circulation line and a radiator at an electrical component module side and circulates coolant between the radiator and the electrical component module. Accordingly, the waste heat of the electrical component module is absorbed into the coolant, the waste heat absorbed into the coolant is dissipated through the radiator, and the electrical component module is cooled through the heat absorption and heat generation of the coolant.

FIG. 1 is a configuration diagram of a general heat pump system, and the heat pump system, which is a vehicle thermal management system, includes major low-voltage electrical components based on low-voltage power (e.g., 12 V), such as an electric water pump (EWP) that circulates coolant to electrical components (PE) and a high-voltage battery (BAT), a multi-valve for coolant, which changes a flow path of the coolant within a vehicle, a 3-way valve for coolant, which configures an air conditioner circuit, adjusts a direction of the coolant, and implements a heat pump system, H/P (high-pressure) EXV, B-Chiller (3-way) EXV, a low-voltage cooling fan that lowers the temperature of a PE room (engine room), and the like, and major high-voltage electrical components based on high-voltage power (e.g., 400 V or 800 V), such as a water heater that raises the temperature, such as passenger heating, battery pre-heating, and the like, an electric compressor that lowers the temperature, such as air conditioner cooling and the like, a high-voltage cooling fan that lowers the temperature of the PE room (engine room), etc.

In order to increase traveling distances of electric vehicles, the application of a thermal management system such as a heat pump system is essential, and in order to configure this, the application of a number of low-voltage and high-voltage power-based electrical components as described above is necessary, and when these are applied individually, there are problems that it is difficult to optimize a system and secure reliability, there is a risk of system control technology leakage, the overall system configuration cost increases, etc.

### DISCLOSURE

### Technical Problem

The present invention has been made in efforts to solve the above problems, and the present invention is directed to providing an integrated controller configured to integrally control two or more of electrical components of a thermal management system for a vehicle, thereby providing advantages, such as securing cost competitiveness, facilitating system optimization, improving system reliability, etc.

### Technical Solution

According to one embodiment of the present invention, an integrated controller for integrally controlling one or more high-voltage electrical components based on high-voltage power and one or more low-voltage electrical component based on low-voltage power among electrical components of a thermal management system for a vehicle includes a circuit board having one microcontroller unit (MCU) or two MCUs and a plurality of driver chips for controlling each of the one or more high-voltage electrical components and the one or more low-voltage electrical components, and is configured to integrally control the one or more high-voltage electrical components and the one or more low-voltage electrical components through the MCU.

The electrical components controlled by the MCU may include a water heater, which is the high-voltage electrical component, and a low-voltage cooling fan, which is the low-voltage electrical component.

The water heater may include a heater unit and a switch element configured to switching-control the heater unit, the low-voltage cooling fan may include a motor unit and a switch element configured to switching-control the motor unit, and the switch elements may be mounted on the circuit board.

The circuit board may be disposed adjacent to a cooling line of the heater unit to dissipate heat from the switch elements using cold air of the cooling line of the heater unit of the water heater.

The circuit board may be disposed adjacent to a coolant inlet side of the cooling line of the heater unit into which coolant flows.

The integrated controller may further include a case that accommodates the circuit board, wherein the case may be configured to be in close contact with the heater unit.

The circuit board and the motor unit of the low-voltage cooling fan may be connected by a hard wire.

The integrated controller may further include a case that accommodates the circuit board, wherein the case may have a low-voltage connector and a high-voltage connector, and the low-voltage connector and the high-voltage connector may each be configured as a single connector.

The circuit board may further include an electromagnetic compatibility (EMC) filter, a DC link, a communication circuit, a switched-mode power supply (SMPS), a regulator, and an isolator, and the EMC filter, the DC Link, the communication circuit, the SMPS, the regulator, and the isolator may be configured to be used in common to control the one or more high-voltage electrical components and the one or more low-voltage electrical components.

The MCU may be configured to receive an upper-level control signal from a vehicle-side upper-level controller and transmit the control signal to each of the plurality of driver chips based on the upper-level control signal.

The MCU may be configured as two MCUs, and the two MCUs may be composed of a first MCU based on high-voltage power and a second MCU based on low-voltage power.

The second MCU may be configured as a one-chip driver together with at least one of the plurality of driver chips.

An integrated control system according to one embodiment of the present invention may include the above integrated controller, and one or more high-voltage electrical components and low-voltage electrical components integrally controlled by the integrated controller.

### Advantageous Effects

According to the present invention, by integrally controlling two or more electrical components using a single integrated controller, it is possible to provide the advantages such as achieving cost competitiveness, facilitating system optimization, and improving system reliability.

### DESCRIPTION OF DRAWINGS

FIG. 1 is a configuration diagram of a general heat pump system.

FIG. 2 is a view showing an integrated controller according to one example of the present invention.

FIG. 3 is an exploded perspective view of FIG. 2.

FIG. 4 is a configuration diagram of an integrated control system according to a first embodiment of the present invention.

FIG. 5 is a configuration diagram of a general water heater.

FIG. 6 is a configuration diagram of a general electric compressor.

FIG. 7 is a configuration diagram of a high-voltage cooling fan.

FIG. 8 is a configuration diagram of an integrated control system of a water heater and an electric compressor.

FIG. 9 is a configuration diagram of an integrated control system of a water heater and a high-voltage cooling fan.

FIG. 10 is a configuration diagram of an integrated control system of a water heater, an electric compressor, and a high-voltage cooling fan.

FIG. 11A to 11C are a view showing the integrated controllers of FIGS. 8, 9, and 10.

FIG. 12 is a view for describing an arrangement structure of a water heater and an integrated controller.

FIG. 13 is a configuration diagram of a general low-voltage cooling fan.

FIG. 14 is a configuration diagram of an integrated control system for a water heater and a low-voltage cooling fan.

### DESCRIPTION OF REFERENCE NUMERALS

10: integrated control system
100: integrated controller
110: case
120: circuit board
150: heat sink
201: first low-voltage electric component (coolant module)
202: second low-voltage electric component (refrigerant module)
203: third low-voltage electric component (low-voltage cooling fan or low-voltage heater)
301: water heater
302: electric compressor
303: high-voltage cooling fan
401: low-voltage cooling fan

### MODE FOR INVENTION

The terms “. . . unit,” “. . . device,” “. . . system,” and the like described throughout the present specification mean a unit that processes the operation that combines one or more functions and may be implemented by hardware, software, or a combination of hardware and software.

Hereinafter, the present invention will be described with reference to the accompanying drawings.

First, the present invention corresponds to an integrated controller for a vehicle, which integrally controls a plurality of electrical components, that is, at least two or more electrical components, of a thermal management system for a vehicle. To this end, the present invention implements integrated control of a plurality of electrical components through a single printed circuit board (PCB) by integrating controller circuits of each of two or more electrical components on the single PCB.

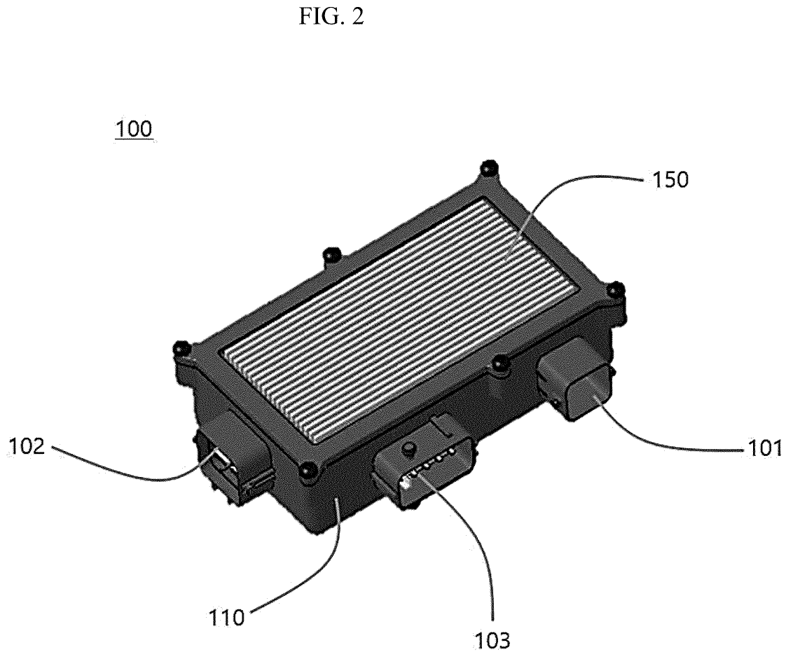

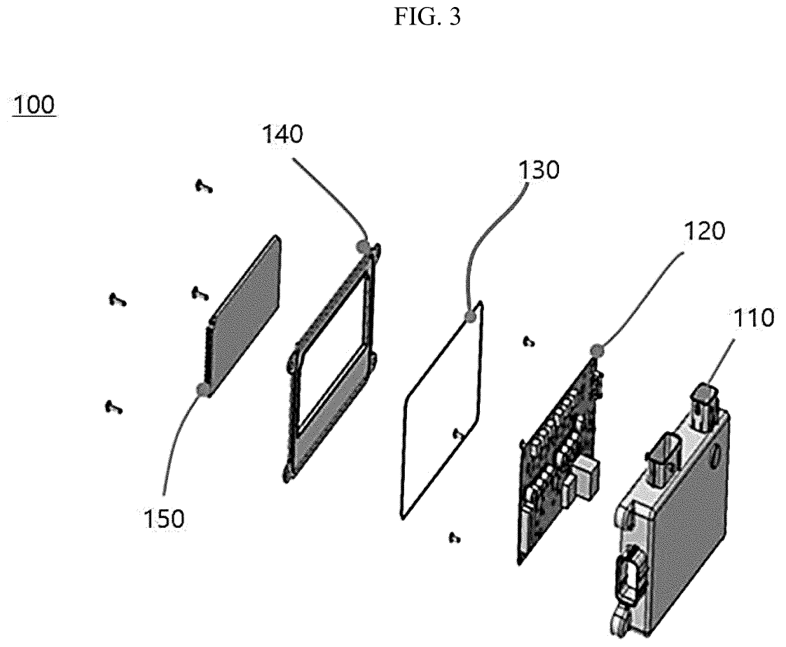

FIG. 2 is a view showing an integrated controller according to one example of the present invention, FIG. 3 is an exploded perspective view of FIG. 2, and as shown, an integrated controller 100 of the present invention generally includes a case 110 and a circuit board 120.

The case 110 corresponds to a housing that stores and protects the circuit board 120.

The case 110 has a number of connectors so that each electrical component may be connected to the circuit board 120. In addition, a heat sink 150 may be provided on one side of the case 110 and used to dissipate heat from the circuit board 120 disposed inside the case 110, and more specifically, various switch elements provided on the circuit board 120 as described below. The heat sink 150 may be installed in a form that is mounted on the cover 140 provided on one side of the case 110, and a gasket 130 may be provided between the cover 140 and the case 110. However, a structure or shape of the case 110 and a coupling relationship between the components are not particularly limited and may be freely designed to perform the above function.

The circuit board 120 is a PCB or PCBA on which various elements and circuits are mounted and corresponds to a controller for controlling a number of electrical components.

A schematic structure of the integrated controller 100 of the present invention is as described above, and hereinafter, based on this, the integrated controller 100 and an integrated control system 10 of the present invention will be described for each embodiment.

### First Embodiment: Integrated Control System For Low-Voltage Electrical Components

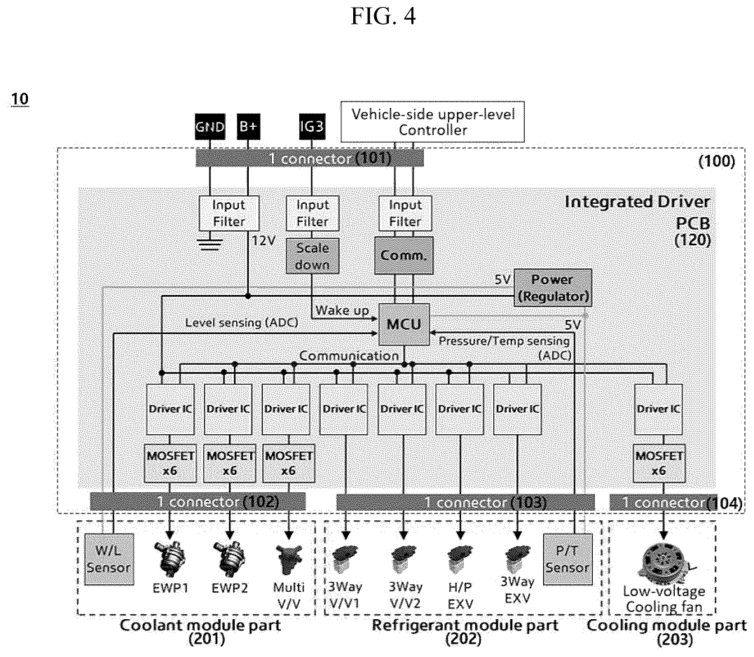

FIG. 4 is a configuration diagram of the integrated control system according to the first embodiment of the present invention, and the system 10 includes the integrated controller 100 and low-voltage electrical components 201, 202, and 203 controlled by the corresponding integrated controller.

The integrated controller 100 of the present example is configured to integrally control low-voltage electrical components based on a low-voltage power source (e.g., 12 V) among electrical components of the thermal management system for a vehicle. More specifically, the integrated controller 100 of the present example is configured to integrate overlapping elements or circuits among controllers of each of the low-voltage electrical components on a single circuit board and integrally control the elements and circuits using a single microcontroller unit (MCU).

As shown, the circuit board 120 of the integrated controller 100 of the present example has one MCU and a plurality of driver chips Driver ICs. Each of the plurality of driver chips is configured to receive a control signal from a single MCU and control each of the low-voltage electrical components. More specifically, the MCU receives an upper-level control signal (communication command) from a vehicle-side upper-level controller and transmits a lower-level control signal to each of the plurality of driver chips based on the received upper-level control signal, and each driver chip controls the low-voltage electrical components for which each driver chip is responsible based on the lower-level control signal received from the MCU.

Here, the driver chip may have motor control software for controlling a motor as needed. That is, at least one of the plurality of driver chips may have control software for controlling at least one of the low-voltage electrical components, for example, a motor of a low-voltage cooling fan embedded therein, which can help improve the control accuracy of the electrical components.

In addition, the circuit board may further include an electromagnetic compatibility (EMC) filter Input Filter, a DC Link, a communication circuit, and a regulator, and these are used in common to control low-voltage electrical components.

That is, conventional thermal management systems for a vehicle require a PCB having a controller, that is, an MCU, an EMC filter Input Filter, a DC Link, a communication circuit, and a regulator for each electrical component, while the present invention integrally implements overlapping elements or circuits among these on a single PCB to prevent duplication of the same configuration, thereby reducing the number of parts and manufacturing costs and reducing the overall packaging of the system. Furthermore, by integrally controlling a plurality of electrical components using a single MCU, it is possible to provide advantages such as easily optimizing the system, securing the control reliability of the system, preventing the leakage of a system control technology, etc.

Referring again to FIG. 4, the low-voltage electrical components to be integrally controlled in the present example may be composed of a first low-voltage electrical component 201, a second low-voltage electrical component 202, and a third low-voltage electrical component 203.

The first low-voltage electrical component 201 is low-voltage electrical components that configures a coolant module and may include electric water pumps EWP and a multi-valve for coolant Multi V/V, the second low-voltage electrical component 202 is low-voltage electrical components that configures a refrigerant module and may include multi-valves for coolant 3Way V/Vs and electric expansion valves H/P EXV and 3Way EXV, and the third low-voltage electrical component 203 is low-voltage electrical components different from the first and second low-voltage electrical components 201 and 202 and may be a low-voltage cooling fan or a low-voltage heater (e.g., a positive temperature coefficient (PCT) heater or the like). FIG. 4 shows only the low-voltage cooling fan as the third low-voltage electrical component 203, but the low-voltage cooling fan may be replaced with a low-voltage heater. Each of the electric water pump, the multi-valve for coolant, the multi-valve for refrigerant, and the electric expansion valve may be configured as one or more valves.

In addition, correspondingly, the plurality of driver chips may include a driver chip for controlling a water pump, a driver chip for controlling a multi-valve for coolant, a driver chip for controlling a multi-valve for refrigerant, a driver chip controlling an expansion valve, and a driver chip controlling a low-voltage cooling fan or a low-voltage heater. That is, the integrated controller 100 of the present invention may be configured so that each driver chip individually controls each electric component.

In addition, the coolant module may further include a water level sensor W/L Sensor, and the refrigerant module may further include a pressure temperature sensor P/T Sensor, and in this case, the MCU may receive information about a water level of coolant (level sensing) from the water level sensor, and receive information about the pressure and temperature of the refrigerant (pressure/temp sensing) from the pressure sensor, and the MCU may generate control signals based on the corresponding pieces of information and transmit the control signals to each driver chip. The water level sensor and the pressure temperature sensor may be connected to a regulator of the circuit board 120 and may receive power from the regulator.

Referring back to FIG. 4, the circuit board 120 may further include a plurality of switch elements MOSFET, and in this case, the plurality of switch elements may include a switch element for switching control of a water pump, a switch element for switching control of a multi-valve for coolant, and a switch element for switching control of a low-voltage cooling fan or a low-voltage heater. These switch elements may be controlled by their respective corresponding driver chips. The switch element of the present example may be configured as a MOSFET element, but is not limited thereto, and may be configured as various types of switch elements such as SCR, GTO, TRIAC, SSS, PTR, IGBT, IGCT, MCT, and the like.

Meanwhile, as described above, the integrated controller 100 of the present invention may further include the case 110 that accommodates the circuit board 120, the heat sink 150 may be provided on one side of the case 110, and the switch elements mounted on the circuit board 120 may be heat-dissipated by the heat sink 150.

In this case, the case 110 may include a first connector 102, a second connector 103, and a third connector 104, a coolant module corresponding to the first low-voltage electrical component 201 may be connected to the first connector 102, a refrigerant module corresponding to the second low-voltage electrical component 202 may be connected to the second connector 103, and a low-voltage cooling fan or low-voltage heater corresponding to the third low-voltage electrical component 203 may be connected to the third connector 104. This provides ease of coupling between the integrated controller 100 and the low-voltage electrical components.

Furthermore, the case may have a power connector 101, and the power connector 101 may be configured as a single connector. Since the power connector 101 is configured as a single connector, there is an advantage that the control system 10 may be configured simply through the integrated controller 100.

### Second Embodiment: Integrated Control System for High-Voltage Electrical Components

The integrated controller 100 of the present example is configured to integrally control high-voltage electrical components based on high-voltage power (e.g., 400 V or 800 V) among electrical components of the thermal management system for a vehicle. More specifically, the integrated controller 100 of the present example is configured to integrate overlapping elements or circuits among controllers of each of the high-voltage electrical components on a single circuit board and integrally control the elements and circuits using one MCU or two MCUs.

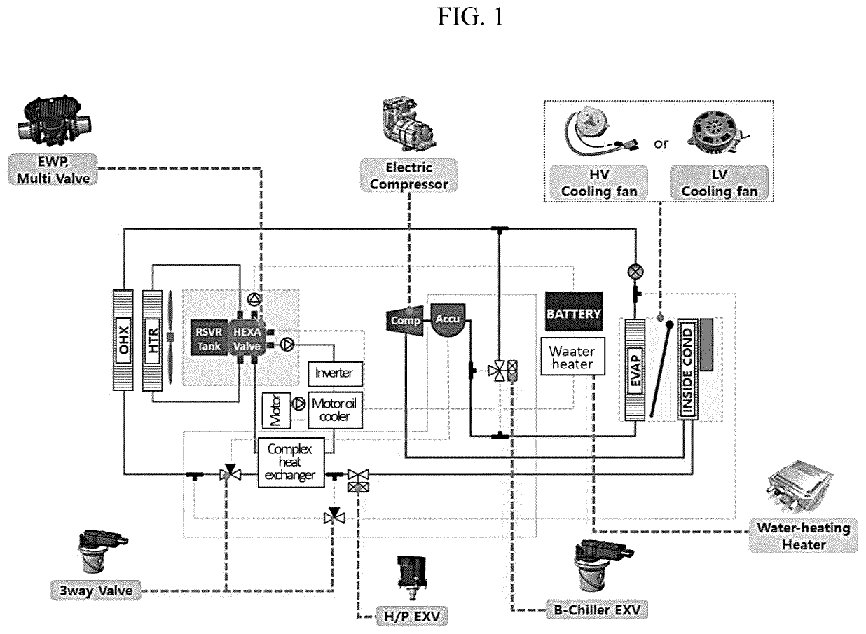

As described through FIG. 1, the water heater, the electric compressor, and the high-voltage cooling fan correspond to main high-voltage electrical components.

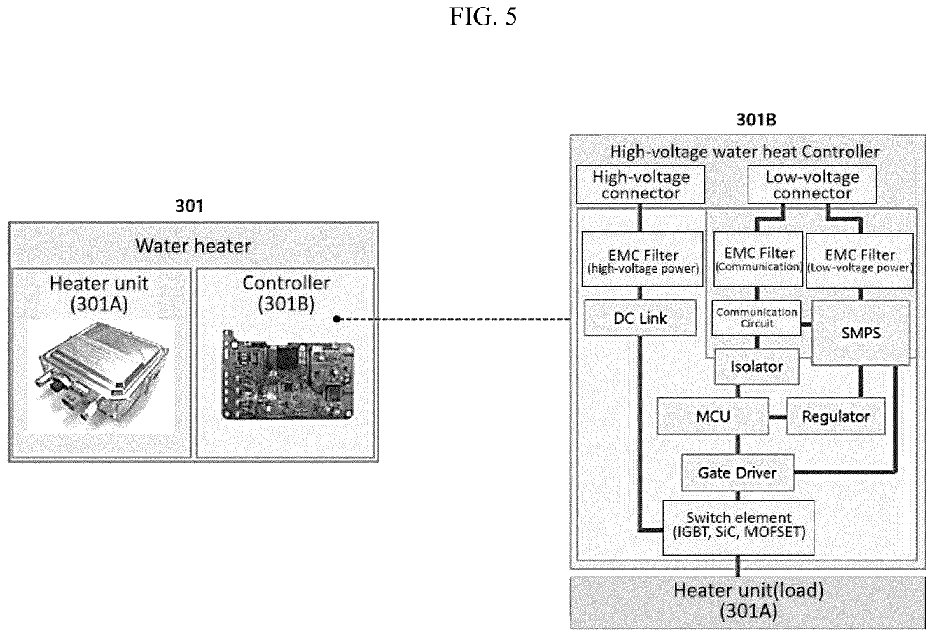

FIG. 5 is a configuration diagram of a general water heater, and a water heater 301 includes a heater unit 301A corresponding to a load and a device unit, and a controller 301B for controlling the heater unit 301A. The heater unit 301A of the water heater is configured such that coolant circulates along a cooling line of the heater unit, cold coolant flows into the heater unit 301A, the coolant is heated while passing through the heater unit, and the heated coolant is discharged from the heater unit 301A.

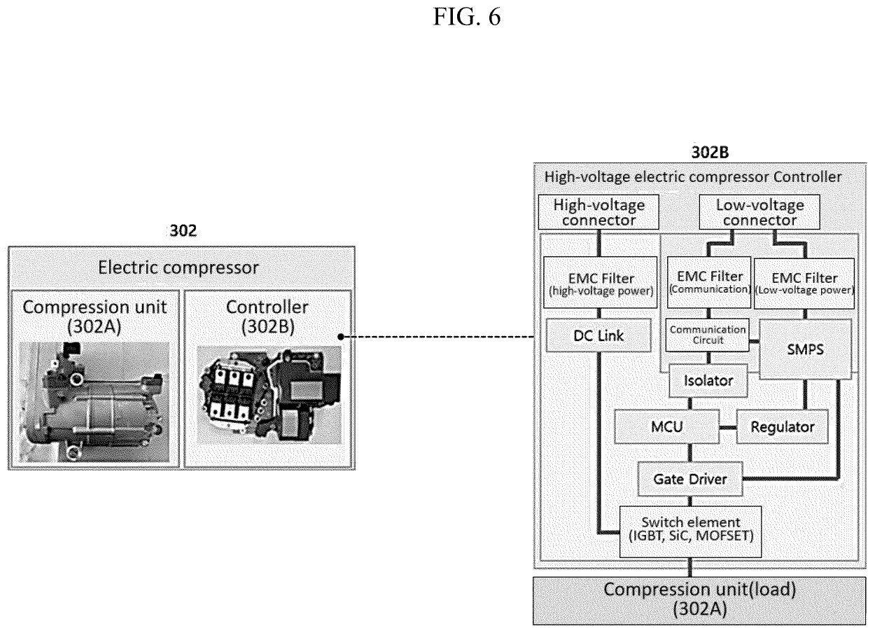

FIG. 6 is a configuration diagram of a general electric compressor, and the electric compressor 302 includes a compression unit 302A corresponding to a load and a device unit, and a controller (inverter) 302B for controlling the compression unit 302A. The electric compressor is configured to compress and discharge refrigerant by a rotational force of an electric motor, and a motor may be included in the compression unit 302A.

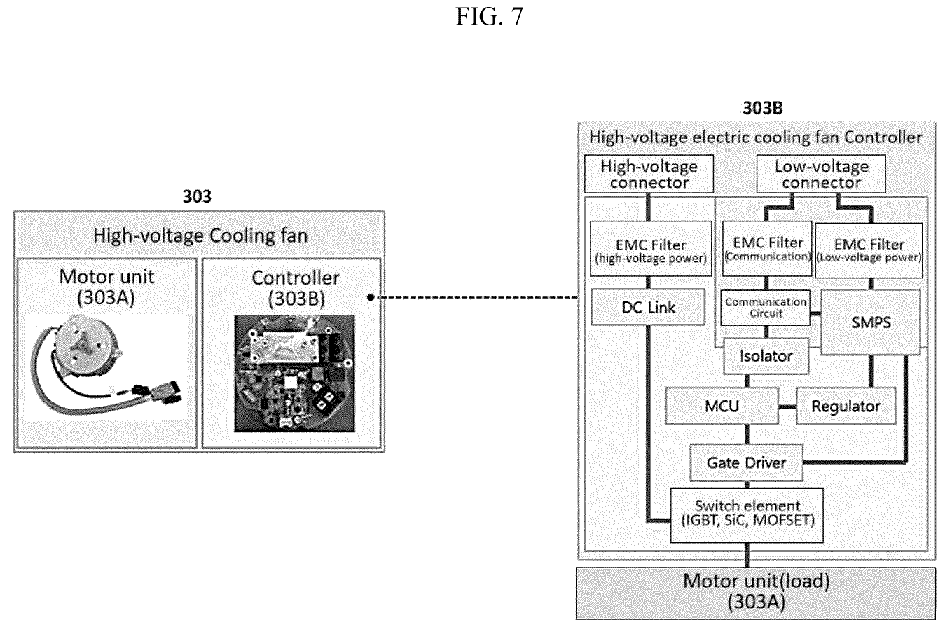

FIG. 7 is a configuration diagram of a general high-voltage cooling fan, and the high-voltage cooling fan 303 includes a motor unit 303A corresponding to a load and a device unit, and a controller (inverter) 303B for controlling the motor unit 303A.

As shown in FIGS. 5 to 7, the controllers 301B, 302B, and 303B of the water heater 301, the electric compressor 302, and the high-voltage cooling fan 303 have many identically overlapping components and circuits, and thus are advantageous in integrating the components and circuits into a single PCB.

In this case, the electric compressor generally dissipates heat from the controller (inverter) using the low temperature of the compression unit and the housing, which is cooled by refrigerant compression during operation, but since the electric compressor is mainly operated in the summer, it is not suitable for dissipating heat from the controller throughout the entire year. In addition, the high-voltage cooling fan generally dissipates heat from the controller (inverter) by air cooling, but it is not suitable in that it is difficult to secure a temperature margin and the application of high current specifications are required.

In contrast, since the water heater is configured to allow cold coolant to be introduced and circulated throughout the entire year regardless of the season, it provides an advantage when used to dissipate heat from the controller. At the same time, the water heater is not only not motor-controlled like the electric compressor or the high-voltage cooling fan, but also has a low control switching frequency, and thus has the characteristics of requiring less resources for control than the electric compressor or the high-voltage cooling fan. Accordingly, it is easy to implement integrated control of the water heater and other high-voltage electrical components using a single MCU.

Based on such a point, the integrated controller 100 of the present example may be configured to integrally control the water heater 301 and one or more high-voltage electrical components excluding the water heater 301. Specifically, the integrated controller 100 of the present example may be configured to integrally control the water heater 301 and the electric compressor 302, integrally control the water heater 301 and the high-voltage cooling fan 303, or integrally control the water heater 301, the electric compressor 302, and the high-voltage cooling fan 303.

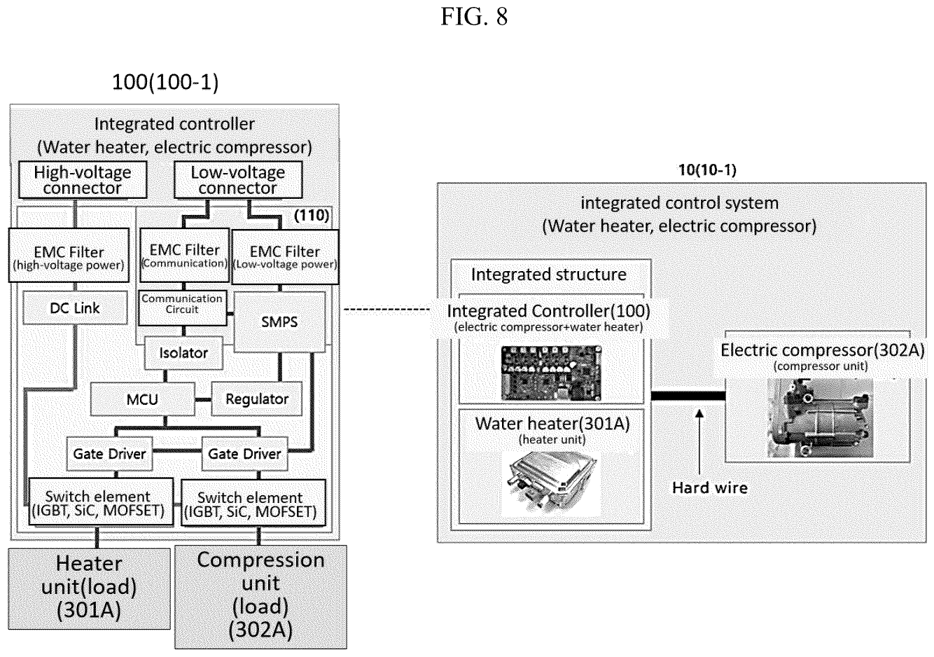

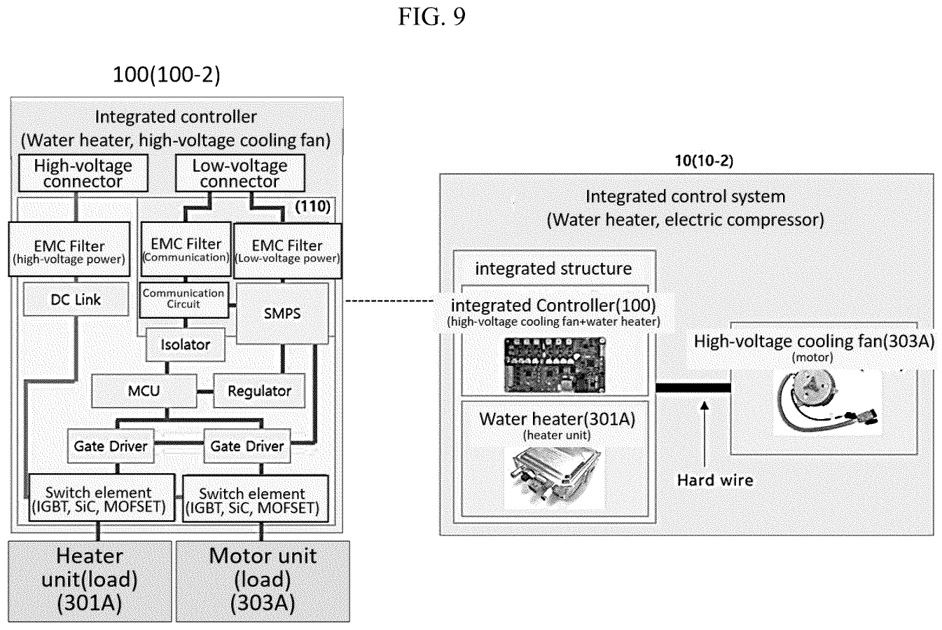

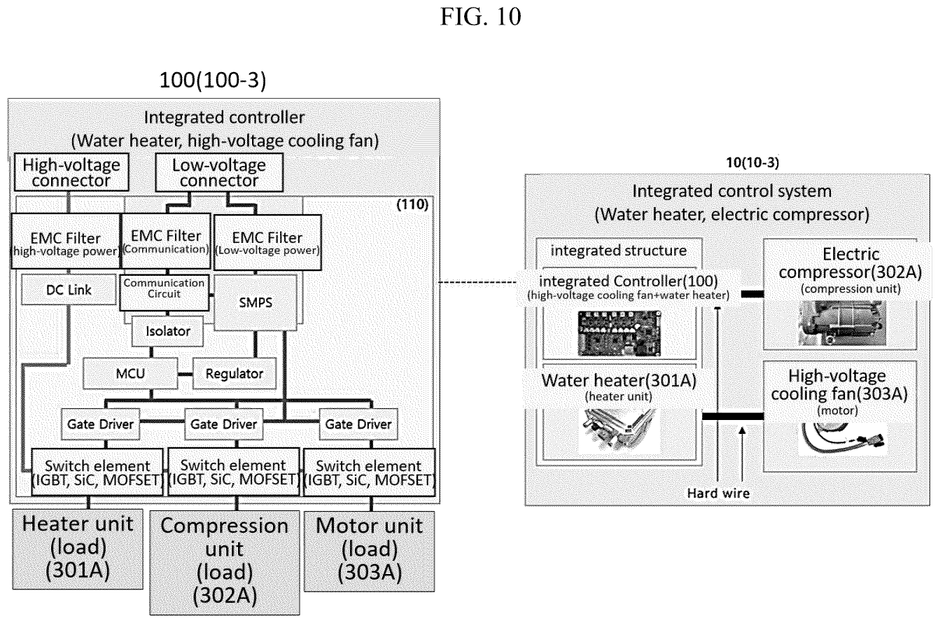

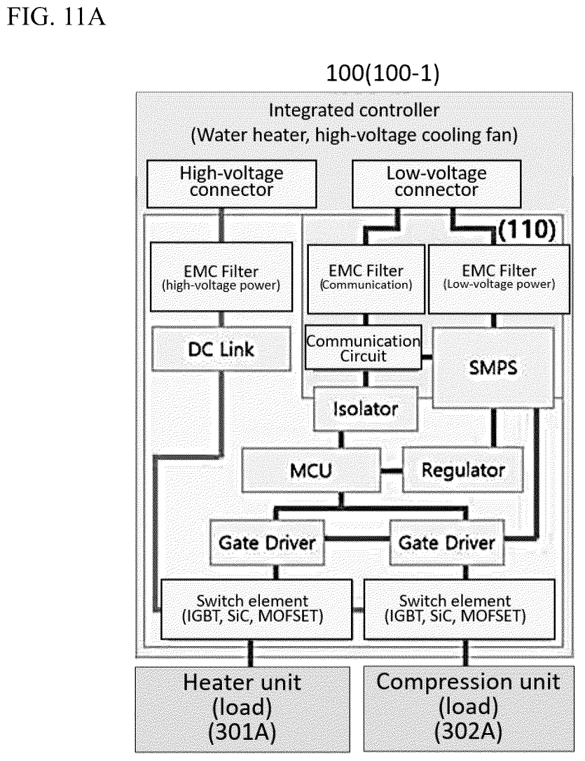

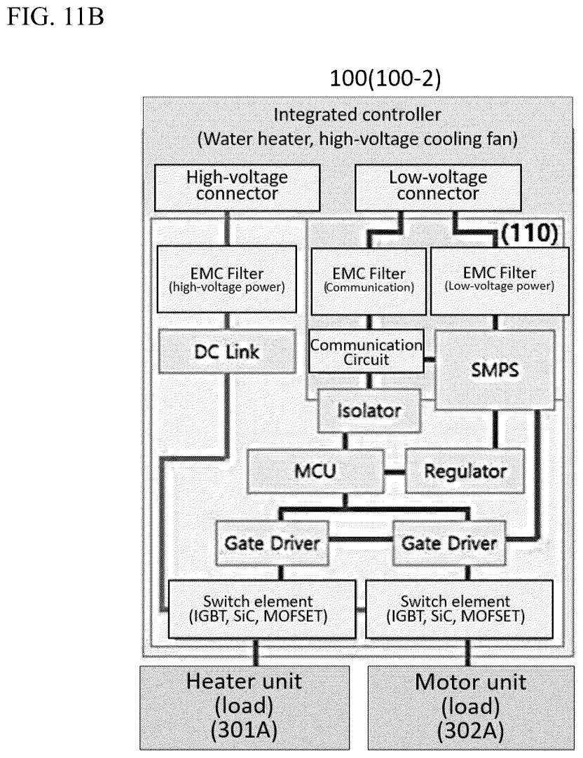

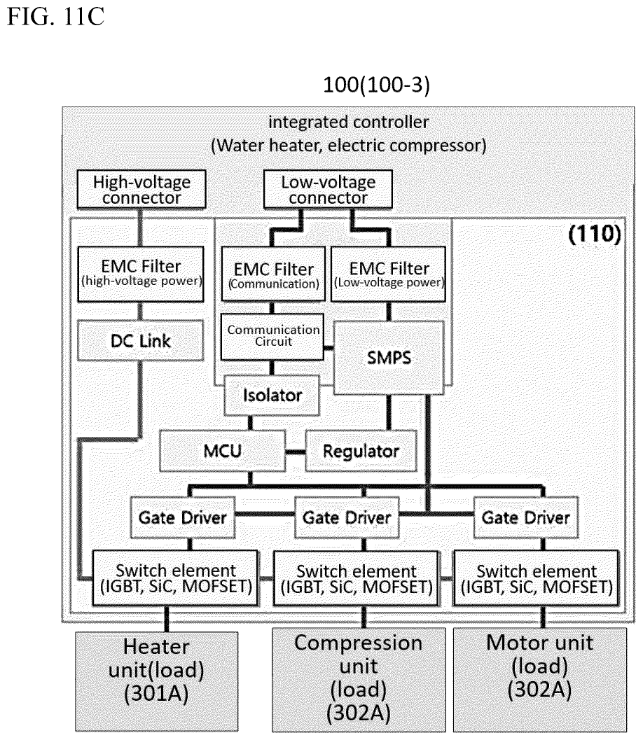

FIG. 8 is a configuration diagram of an integrated control system of a water heater and an electric compressor, FIG. 9 is a configuration diagram of an integrated control system of a water heater and a high-voltage cooling fan, FIG. 10 is a configuration diagram of an integrated control system of a water heater, an electric compressor, and a high-voltage cooling fan, and FIG. 11A to 11C are a view showing the integrated controllers of FIGS. 8, 9, and 10.

As shown, the circuit board 120 of the integrated controller 100 of the present example has one MCU and a plurality of driver chips Gate Drivers, and each of the plurality of driver chips is configured to receive control signals from the MCU and control each of the high-voltage electrical components, that is, the water heater 301, the electric compressor 302, and the high-voltage cooling fan 303. More specifically, as described above, the MCU receives the upper-level control signal (communication command) from a vehicle-side upper-level controller and transmits a control signal to each of the plurality of driver chips based on the received upper-level control signal, and each driver chip controls the high-voltage electrical components for which each driver chip is responsible based on the received control signal.

In this case, as shown, it is preferable to configure the MCU as a single MCU in terms of reducing manufacturing costs, integrated control, etc. However, although not shown, the MCU may be configured as two MCUs as needed in consideration of the overall control resources and the like, and in this case, each of the two MCUs may be composed of a main MCU and a sub MCU.

In addition, the circuit board 120 further has an EMC filter (for high-voltage power, communication, low-voltage power, or the like), a DC link, a communication circuit, an SMPS, a regulator, and an isolator, which are used in common to control the high-voltage electrical components.

That is, the integrated controller of the present example is implemented by integrating the controllers 301B, 302B, and 303B of the high-voltage electrical components that are present as a single independent component in the conventional thermal management system for a vehicle, that is, the water heater 301, the electric compressor 302, and the high-voltage cooling fan 303, on a single PCB, and the advantages thereof are as described above. Here, some components on the circuit board 120, such as a SMPS, a DC link, an EMC filter, and the like, may have increased capacity compared to the components of the single controller of each conventional electrical component in order to respond to the operation of two or more high-voltage electrical components.

Referring back to FIGS. 8 to 11, the device units of the high-voltage electrical components, that is, the heater unit 301A of the water heater, the compression unit 302A of the electric compressor, and the motor unit 303A of the high-voltage cooling fan, may be connected to the integrated controller 100 with a hard wire. The hard wire is a circuit that does not include electronic components such as resistors or capacitors and switches, and by adopting a hard wire in this way, it is possible to provide advantages such as improving connectivity between the integrated controller 100 and the high-voltage electrical components and stability of the entire system.

In addition, the integrated controller 100 of the present example may have one low-voltage connector and one high-voltage connector. These low-voltage connectors and high-voltage connectors are power connectors, and low and high voltages may be applied to each connector so that an appropriate voltage may be applied to each component or circuit on the circuit board, and at the same time, the power supply to the electrical components may be integrally implemented through the integrated controller 100, thereby improving the convenience of use.

Additionally regarding FIGS. 8 to 11, switch elements of each of the high-voltage electrical components are mounted on the circuit board 120. The switch elements may include a switch element that switching-controls the heater unit 301A of the water heater 301, a switch element that switching-controls the compression unit 302A of the electric compressor 302, and a switch element that switching-controls the motor unit 303A of the high-voltage cooling fan 303, and these switch elements may be controlled by each driver chip Gate Driver. The switch element of the present example may be composed of an IGBT or SiC MOSFET to control high-voltage electrical components, but is not limited thereto and may be configured as various types of switch elements.

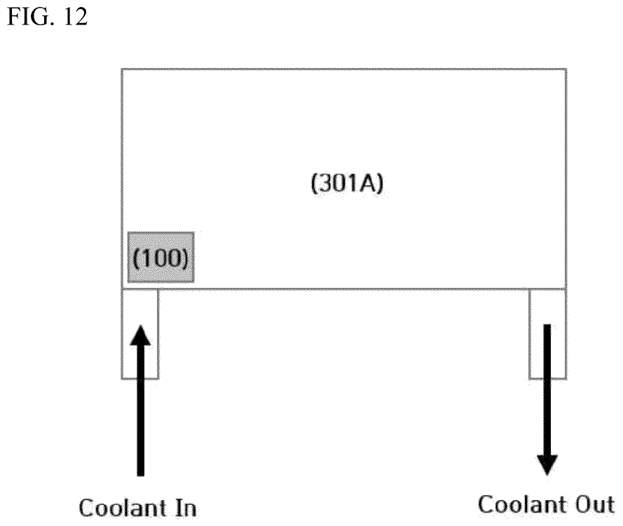

In this case, as described above, cold coolant flows into the heater unit 301A of the water heater 301, which may be used to cool the heat generation of the switch element. FIG. 12 is a view for describing the arrangement structure of the water heater and the integrated controller, and as shown, a cooling line in which coolant circulates may be formed in the heater unit 301A of the water heater 301, and by arranging the integrated controller 100 adjacent to this cooling line, the cooling performance of the switch elements can be secured.

Here, since the temperature of the coolant flowing into a coolant inlet Coolant In of the cooling line of the heater unit 301A is lower than the temperature of a coolant discharged through a coolant outlet Coolant Out, arranging the integrated controller 100 close to the coolant inlet side of the cooling line is advantageous in terms of cooling performance, and furthermore, arranging the integrated controller 100 in close contact with the heater unit 301A is advantageous in terms of increasing cooling efficiency.

Based on such a point, the integrated controller 100 of the present example may be configured such that the circuit board 120 of the integrated controller 100 is disposed adjacent to the coolant inlet side of the cooling line of the heater unit 301A into which the coolant flows, and at the same time, is mounted and coupled to the heater unit 301A and integrally configured with the heater unit 301A. That is, the integrated controller 100 of the present example may be configured such that the case 110 of the integrated controller 100 is in close contact with the heater unit 301A, and in this case, the heat sink 150 may be provided on a surface of the case 110 that is in close contact with the heater unit 301A as described above.

### Third Embodiment: Integrated Control System For High-Voltage/Low-Voltage Electrical Components

The integrated controller 100 of the present example is configured to integrally control one or more high-voltage electrical components based on high-voltage power and one or more low-voltage electrical component based on low-voltage power among the electrical components of the thermal management system for a vehicle.

That is, unlike the first embodiment configured to integrally control low-voltage electrical components and the second embodiment configured to integrally control high-voltage electrical components, the present embodiment differs in that it is configured to integrally control both a high-voltage electrical component and a low-voltage electrical component. Hereinafter, the overlapping descriptions of the first and second embodiments will be omitted, and differences will be mainly described.

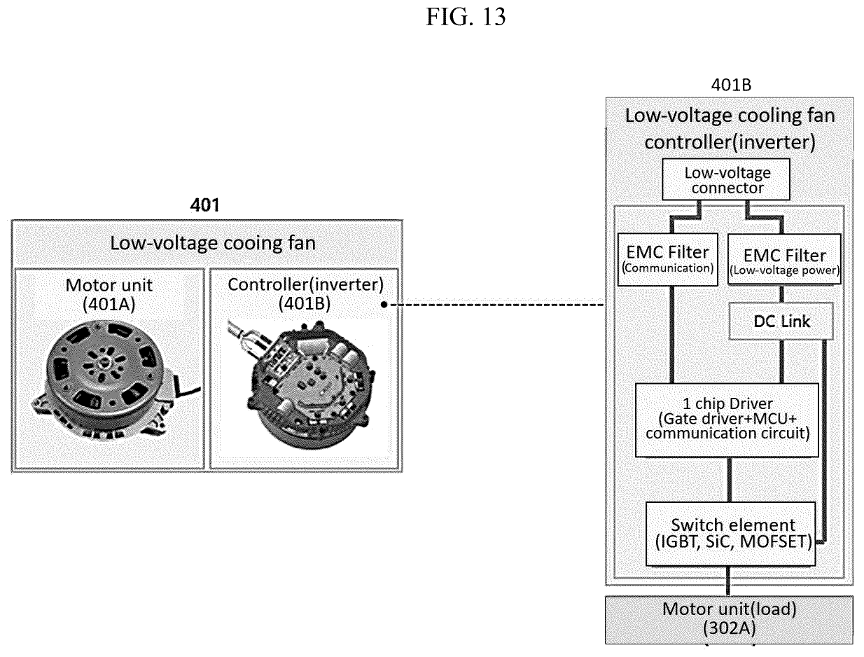

In the present example, the electrical components to be integrally controlled may be composed of the water heater 301, which is a high-voltage electrical component, and a low-voltage cooling fan 401, which is a low-voltage electrical component. The general configuration of the water heater 301 is as described above in FIG. 5. FIG. 13 is a configuration diagram of a general low-voltage cooling fan, and the low-voltage cooling fan 401 includes a motor unit 401A corresponding to a load and a device unit, and a controller (inverter) 401B for controlling the motor unit 401A.

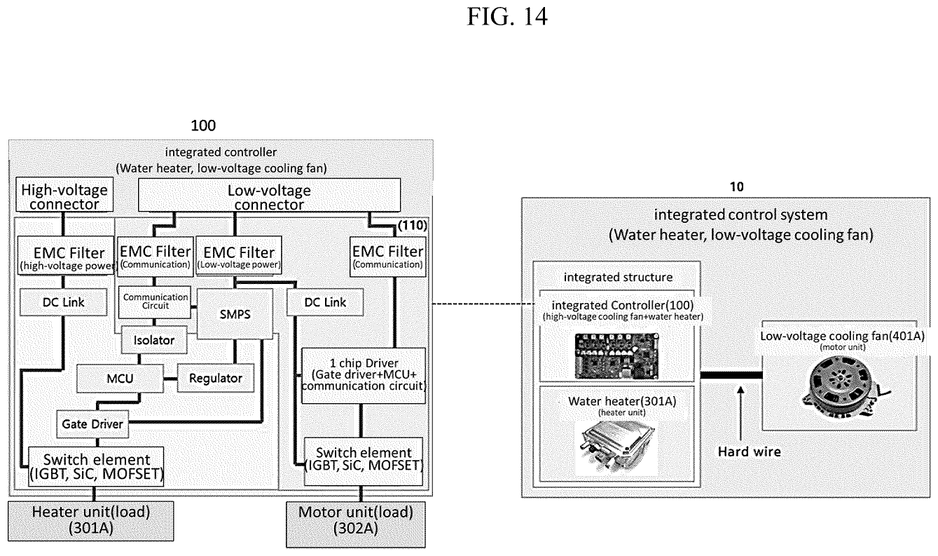

FIG. 14 is a configuration diagram of an integrated control system of a water heater and a low-voltage cooling fan, and the integrated control system 10 of the present example may be configured by integrating the controller 301B of the water heater 301 and the controller (inverter) 401B of the low-voltage cooling fan 401 into a single PCB to configure the integrated controller 100, and connecting the integrated controller 100 to the heater unit 301A and the motor unit 401A with a hard wire. That is, the circuit board 120 of the integrated controller 100 of the present example may include an MCU, an EMC filter, a DC Link, a communication circuit, an SMPS, a regulator, and an isolator, and these may be used in common to control the water heater and the low-voltage cooling fan.

Here, the MCU may be configured as two MCUs in which one may be configured based on high-voltage power and the other may be configured based on low-voltage power, and the first MCU based on the high-voltage power may be configured to control the heater unit 301A of the water heater 301, which is a high-voltage electrical component, and the second MCU based on the low-voltage power may be configured to control the motor unit 401A of the low-voltage cooling fan 401, which is a low-voltage electrical component.

Furthermore, as shown in FIG. 14, in the case of the circuit board on the low-voltage cooling fan side, a single chip driver 1 chip Driver that integrates a gate driver, an MCU, and a communication circuit can be applied, thereby simplifying the control circuit. Furthermore, by applying a water-cooling structure using the cooling line of the water heater, the capacity of the DC link can be reduced, low temperature specification components can be applied, and the current specifications of the switch components can be lowered, thereby implementing a more compact integrated controller.

As described above, the present invention can provide various advantages such as securing cost competitiveness, facilitating system optimization, and improving system reliability by configuring an integrated controller by integrating controller circuits of each of two or more electrical components on a single PCB and implementing integrated control of two or more electrical components using the integrated controller.

Although the embodiments of the present invention have been described above with reference to the accompanying drawings, those skilled in the art to which the present invention pertains will understand that the present invention can be carried out in other specific forms without changing the technical spirit or essential features thereof. Accordingly, it should be understood that the above-described embodiments are illustrative and not restrictive in all aspects.

1. An integrated controller for integrally controlling one or more high-voltage electrical components based on high-voltage power and one or more low-voltage electrical component based on low-voltage power among electrical components of a thermal management system for a vehicle, the integrated controller comprising:
a circuit board having one microcontroller unit (MCU) or two MCUs and a plurality of driver chips for controlling each of the one or more high-voltage electrical components and the one or more low-voltage electrical components, and
configured to integrally control the one or more high-voltage electrical components and the one or more low-voltage electrical components through the MCU.

2. The integrated controller of claim 1, wherein the electrical components controlled by the MCU include:
a water heater, which is the high-voltage electrical component; and
a low-voltage cooling fan, which is the low-voltage electrical component.

3. The integrated controller of claim 2, wherein the water heater includes a heater unit and a switch element configured to switching-control the heater unit,
the low-voltage cooling fan includes a motor unit and a switch element configured to switching-control the motor unit, and
the switch elements are mounted on the circuit board.

4. The integrated controller of claim 3, wherein the circuit board is disposed adjacent to a cooling line of the heater unit to dissipate heat from the switch elements using cold air of the cooling line of the heater unit of the water heater.

5. The integrated controller of claim 4, wherein the circuit board is disposed adjacent to a coolant inlet side of the cooling line of the heater unit into which coolant flows.

6. The integrated controller of claim 4, further comprising a case that accommodates the circuit board,
wherein the case is configured to be in close contact with the heater unit.

7. The integrated controller of claim 3, wherein the circuit board and the motor unit of the low-voltage cooling fan are connected by a hard wire.

8. The integrated controller of claim 2, further comprising a case that accommodates the circuit board,
wherein the case has a low-voltage connector and a high-voltage connector, and
the low-voltage connector and the high-voltage connector are each configured as a single connector.

9. The integrated controller of claim 1, wherein the circuit board further includes an electromagnetic compatibility (EMC) filter, a DC link, a communication circuit, a switched-mode power supply (SMPS), a regulator, and an isolator, and
the EMC filter, the DC Link, the communication circuit, the SMPS, the regulator, and the isolator are configured to be used in common to control the one or more high-voltage electrical components and the one or more low-voltage electrical components.

10. The integrated controller of claim 1, wherein the MCU is configured to receive an upper-level control signal from a vehicle-side upper-level controller and transmit the control signal to each of the plurality of driver chips based on the upper-level control signal.

11. The integrated controller of claim 1, wherein the MCU is configured as two MCUs, and
the two MCUs are composed of a first MCU based on high-voltage power and a second MCU based on low-voltage power,

12. The integrated controller of claim 11, wherein the second MCU is configured as a one-chip driver together with at least one of the plurality of driver chips,

13. An integrated control system comprising:
the integrated controller of claim 1; and
one or more high-voltage electrical components and low-voltage electrical components integrally controlled by the integrated controller.
